(19) United States
(12) Patent Application Publication
(10) Pub. No.: US 2022/0399444 A1
(43) Pub. Date: Dec. 15, 2022

(54) SEMICONDUCTOR DEVICE AND FABRICATION METHOD THEREOF

(71) Applicant: INNOSCIENCE (SUZHOU) SEMICONDUCTOR CO., LTD., SUZHOU (CN)

(72) Inventors: Hao LI, ZHUHAI (CN); Anbang ZHANG, ZHUHAI (CN); Haoning ZHENG, ZHUHAI (CN)

(21) Appl. No.: 17/273,721

(22) PCT Filed: Jan. 12, 2021
(86) PCT No.: PCT/CN2021/071257

§ 371 Date: Mar. 4, 2021

(51) Int. Cl. H01L 29/417; H01L 29/66; H01L 29/778; H01L 29/20; H01L 29/40

(52) U.S. Cl. CPC H01L 29/41775; H01L 29/66462; H01L 29/7787; H01L 29/2003; H01L 29/401; H01L 29/402

(57) ABSTRACT

The present disclosure provides a semiconductor device and a fabrication method thereof. The semiconductor device includes a semiconductor stack and a first ohmic contact. The semiconductor stack is formed on a substrate. The semiconductor stack has a first nitride semiconductor layer and a second nitride semiconductor layer formed on the first nitride semiconductor layer. The second nitride semiconductor layer has a wider bandgap than that of the first nitride semiconductor layer. The first ohmic contact is disposed over the semiconductor stack. The first to ohmic contact has a first opening exposing the first nitride semiconductor layer.

### BACKGROUND

### 1. Technical Field

The present disclosure relates to a semiconductor device and a fabrication method thereof.

### 2. Description of the Related Art

Components including direct bandgap semiconductors, for example, semiconductor components including group III-V materials or group III-V compounds (Category: III-V compounds) can operate or work under a variety of conditions or in a variety of environments (e.g., at different voltages and frequencies) due to their characteristics.

The semiconductor components may include a heterojunction is bipolar transistor (HBT), a heterojunction field effect transistor (HFET), a high-electron-mobility transistor (HEMT), a modulation-doped FET (MODFET) and the like.

### SUMMARY OF THE INVENTION

In some embodiments of the present disclosure, a semiconductor device is provided, which includes a semiconductor stack and a first ohmic contact. The semiconductor stack is formed on a substrate. The semiconductor stack has a first nitride semiconductor layer and a second nitride semiconductor layer formed on the first nitride semiconductor layer. The second nitride semiconductor layer has a wider bandgap than that of the first nitride semiconductor layer. The first ohmic contact is disposed over the semiconductor stack. The first ohmic contact has a first opening exposing the first nitride semiconductor layer.

In some embodiments of the present disclosure, a semiconductor device is provided, which includes a semiconductor stack, a first drain electrode portion, and a second drain electrode portion. The semiconductor stack is formed on a substrate. The semiconductor stack has a first nitride semiconductor layer and a second nitride semiconductor layer formed on the first nitride semiconductor layer. The second nitride semiconductor layer has a wider bandgap than that of the first nitride semiconductor layer. The first drain electrode portion and the second drain electrode portion are disposed over the second nitride semiconductor layer. A space between the first drain electrode portion and the second drain electrode portion exposes the first nitride semiconductor layer.

In some embodiments of the present disclosure, a method for manufacturing a semiconductor device is provided. The method includes is forming a semiconductor stack on a substrate, which includes forming a first nitride semiconductor layer on the substrate, and forming a second nitride semiconductor layer on the first nitride semiconductor layer. The method also includes forming a first ohmic contact over the semiconductor stack. The first ohmic contact has an opening exposing the first nitride semiconductor layer.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1A is a cross-sectional view of a semiconductor device according to some embodiments of the present disclosure;

FIG. 1B is a top view of a portion of a semiconductor device according to some embodiments of the present disclosure;

FIG. 2 is a top view of a semiconductor device according to some embodiments of the present disclosure;

FIG. 3 is a top view of a portion of a semiconductor device according to some embodiments of the present disclosure;

FIG. 4A is a cross-sectional view of a semiconductor device according to some embodiments of the present disclosure;

FIG. 4B is a cross-sectional view of a semiconductor device according to some embodiments of the present disclosure;

FIG. 4C is a cross-sectional view of a semiconductor device according to some embodiments of the present disclosure;

FIG. 5A is a cross-sectional view of a semiconductor device according to some embodiments of the present disclosure;

FIG. 5B is a top view of a portion of a semiconductor device according to some embodiments of the present disclosure;

FIG. 6A is a cross-sectional view of a semiconductor device according to some embodiments of the present disclosure;

FIG. 6B is a top view of a portion of a semiconductor device according to some embodiments of the present disclosure;

FIGS. 7A, 7B, 8A, 8B, 9A, 9B, 10A and 10B illustrate several operations in manufacturing a semiconductor device according to some embodiments of the present disclosure; and

FIG. 11 is a cross-sectional view of a semiconductor device according to some embodiments of the present disclosure.

### PREFERRED EMBODIMENT OF THE PRESENT INVENTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

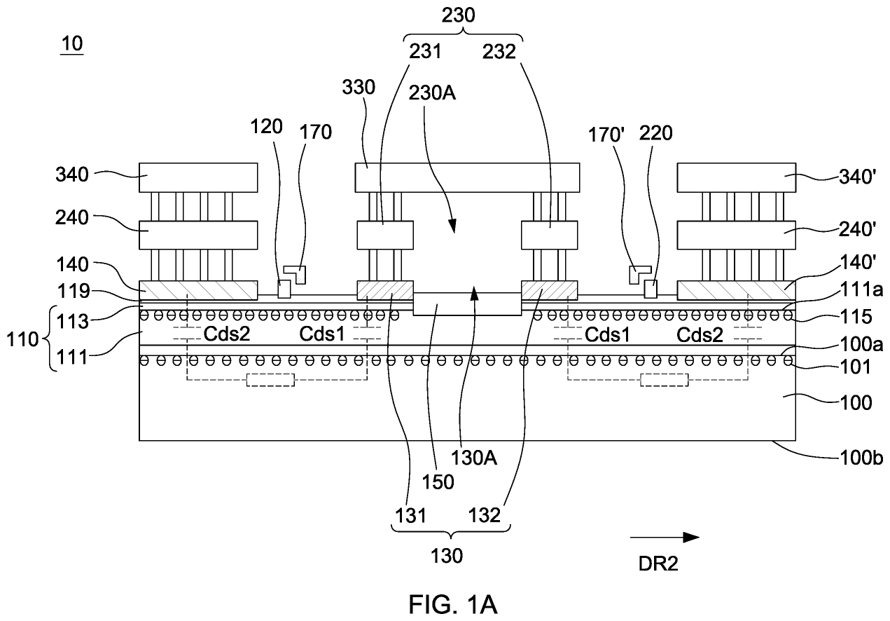

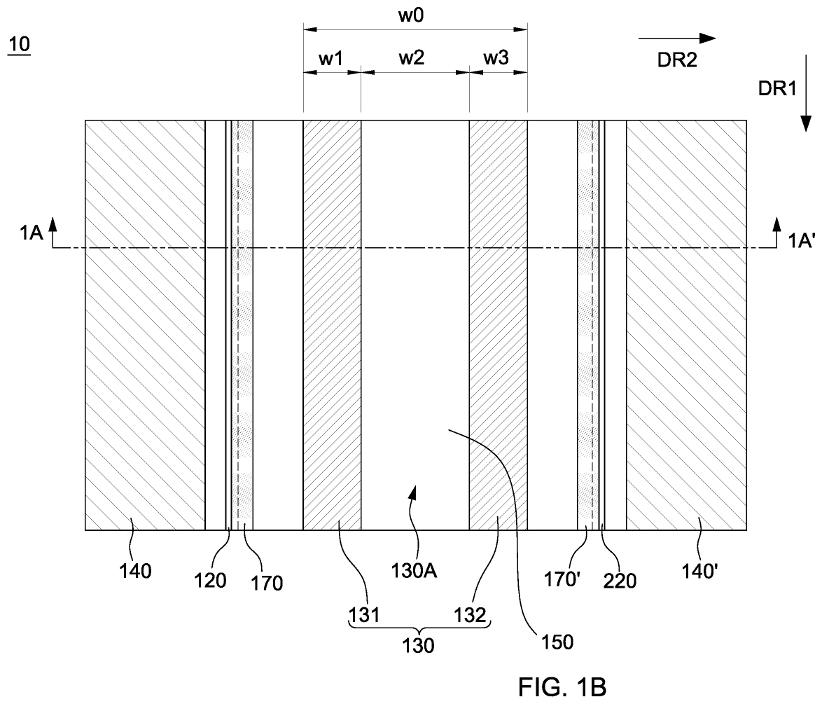

FIG. 1A is a cross-sectional view of a semiconductor device 10 according to some embodiments of the present disclosure. The semiconductor device 10 may be adopted in an RF device, such as a power RF device, but the present disclosure is not limited thereto. The semiconductor device 10 can work at relatively great or high voltage level (e.g. greater than 600 V) to function as a high voltage transistor. The semiconductor device 10 can work at relatively great or high frequency (e.g. greater than 6 GHz).

The semiconductor device 10 may include a substrate 100, a semiconductor stack 110, gates 120 and 220, ohmic contacts 130, 140 and 140′, a structure 150, field plates 170 and 170′, and patterned conductive layers 230, 330, 240, 340, 240′ and 340′.

The substrate 100 may include, without limitation, silicon (Si), doped Si, silicon carbide (SiC), germanium silicide (SiGe), gallium arsenide (GaAs), sapphire, silicon on insulator (SOI), or other suitable material(s). The substrate 100 may further include a doped region, for example, a p-well, an n-well, or the like. The substrate 100 may include impurity. The substrate 100 may include a p-type silicon substrate. The substrate 100 has a surface 100a (also referred to as “an upper surface”) and a surface 100b (also referred to as “a bottom surface”) opposite to the surface 100a. The substrate 100 may include a parasitic conduction layer 101 adjacent to the surface 100a of the substrate 100.

The semiconductor stack 110 may include nitride semiconductor is layers 111 and 113. The nitride semiconductor layer 111 may be formed on the surface 100a of the substrate 100. The nitride semiconductor layer 111 has a surface 111a. The nitride semiconductor layer 111 may include, without limitation, a group III nitride, for example, a compound InₓAl_{y}Ga_{1-x-y}N, in which x+y≤1. The group III nitride may further include, but is not limited to, for example, a compound Al_{y}Ga_{(1-y)}N, in which y≤1. For example, the nitride semiconductor layer 111 may include a GaN layer having a bandgap of about 3.4 eV.

The nitride semiconductor layer 113 (also referred to as “a barrier layer”) may be formed on the surface 111a of the nitride semiconductor layer 111. The nitride semiconductor layer 113 may have a greater bandgap than that of the nitride semiconductor layer 111. The nitride semiconductor layer 113 may be in direct contact with the nitride semiconductor layer 111. The nitride semiconductor layer 113 may include, without limitation, a group III nitride, for example, a compound InₓAl_{y}Ga_{1-x-y}N, in which x+y≤1. The group III nitride may further include, but is not limited to, for example, a compound Al_{y}Ga_{(1-y)}N, in which y≤1. For example, the nitride semiconductor layer 113 may include AlGaN having a band gap of about 4 eV.

A heterojunction may be formed between the nitride semiconductor layer 111 and the nitride semiconductor layer 113, e.g., at an interface of the nitride semiconductor layer 111 and the nitride semiconductor layer 113, and the polarization of the heterojunction of different nitrides forms a two-dimensional electron gas (2DEG) region 115 adjacent to the interface of the nitride semiconductor layer 111 and the nitride semiconductor layer 113. The 2DEG region 115 may be formed in the nitride semiconductor layer 111. The nitride semiconductor layer 111 can provide electrons to or remove electrons from the 2DEG region 115, thereby controlling the conduction of the semiconductor device 10. Although it is not illustrated in is FIG. 1A for simplification, however, it is contemplated that a super lattice layer may be formed between the substrate 100 and the stack of nitride semiconductor layers 111 and 113 to facilitate operation of the semiconductor device 10 in a relatively high voltage level.

A cap layer 119 may be optionally formed on the nitride semiconductor layer 113. The cap layer 119 may include a GaN layer, an in-situ SiN layer, an in-situ AN layer, or a combination thereof. The cap layer 119 may directly contact the nitride semiconductor layer 113. The cap layer 119 may be between the nitride semiconductor layer 113 and the gate layer 120. The cap layer 119 may be between the nitride semiconductor layer 113 and the ohmic contact 130. The cap layer 119 may be between the nitride semiconductor layer 113 and the ohmic contact 140.

The gate 120 may be disposed over the semiconductor stack 110. The gate 120 may include a conductive layer. The gate 120 may be or include a gate metal. The gate metal may include, for example, but is not limited to, titanium (Ti), tantalum (Ta), tungsten (W), aluminum (Al), cobalt (Co), copper (Cu), nickel (Ni), platinum (Pt), lead (Pb), molybdenum (Mo) and compounds thereof (such as, but not limited to, titanium nitride (TiN), tantalum nitride (TaN), other conductive nitrides, or conductive oxides), metal alloys (such as aluminum-copper alloy (Al—Cu)), or other suitable materials.

The gate 220 may be disposed on a side of the ohmic contact 130 opposite the gate 120. The material of the gate 220 may be similar to that of the gate 120 and the description thereof is omitted thereinafter.

The ohmic contact 130 (also referred to as “a drain electrode”) may be disposed over the semiconductor stack 110. The ohmic contact 130 may have an opening 130A. The opening 130A may expose the nitride semiconductor layer 111. The ohmic contact 130 may include, for example, is without limitation, a conductor material. The conductor material may include, but is not limited to, for example, metals, alloys, doped semiconductor materials (e.g., doped crystalline silicon), or other suitable conductor materials.

The ohmic contact 130 may include a portion 131 (also referred to as “a drain electrode portion”) and a portion 132 (also referred to as “a drain electrode portion”) spaced apart by the opening 130A. A space between the portion 131 and the portion 132 may expose the nitride semiconductor layer 111.

The ohmic contact 140 (also referred to as “a source electrode”) may be disposed over the semiconductor stack 110 and on a side of the gate 120 opposite the ohmic contact 130. The ohmic contact 140′ (also referred to as “a source electrode”) may be disposed over the semiconductor stack 110 and on a side of the gate 220 opposite the ohmic contact 130. The ohmic contacts 140 and 140′ may include, for example, without limitation, a conductor material. The conductor material may include, but is not limited to, for example, metals, alloys, doped semiconductor materials (e.g., doped crystalline silicon), or other suitable conductor materials.

The structure 150 may be in the semiconductor stack 110 and exposed by the opening 130A. The structure 150 may be directly below the space between the portion 131 and the portion 132 of the ohmic contact 130. A material of the structure 150 may be different from a material of the nitride semiconductor layer 113. The structure 150 may include a doped nitride semiconductor material with a dopant including He⁺, N⁺, O⁺, Fe⁺, Ar⁺, Kr⁺, or a combination thereof, a doped group III-V layer, an n-type polysilicon layer, a dielectric material, or a combination thereof.

The field plate 170 may be disposed adjacent to the gate 120. The field plate 170′ may be disposed adjacent to the gate 220. The field plate 170 may be disposed between the gate 120 and the ohmic contact 130 from is a top view perspective. The field plate 170′ may be disposed between the gate 220 and the ohmic contact 130 from a top view perspective. The field plate 170 may be partially above the gate 120. The field plate 170′ may be partially above the gate 220. The field plates 170 and 170′ can include a conductive material. The field plates 170 and 170′ can be at zero potential and connected to the ohmic contacts 140 and 140′. The field plates 170 and 170′ can allow the electric field between the conductor structures (for example, the gate 120, the gate 220, the ohmic contact 130, and the ohmic contact 140) to distribute evenly, improve the tolerance to voltage, and permit the voltage to release slowly, thereby improving the device reliability. In addition, the field plate 170 electrically connecting to the ohmic contact 140 (which can also be referred to as “the source electrode”) can facilitate the balance of the electric potential distribution in the nitride semiconductor layer 111.

The patterned conductive layer 230 may be disposed over the ohmic contact 130. The patterned conductive layer 230 may have an opening 230A. The patterned conductive layer 230 may include a portion 231 and a portion 232 spaced apart from the portion 231 by the opening 230A. The portions 231 and 232 may extend substantially in parallel to the gate 120. The opening 230A of the patterned conductive layer 230 may be directly above the opening 130A. The opening 230A of the patterned conductive layer 230 may be directly above the structure 150. The opening 130A of the ohmic contact 130 may be aligned with the opening 230A of the patterned conductive layer 230.

The patterned conductive layer 330 may be disposed over the patterned conductive layer 230. The patterned conductive layer 330 may cover the opening 230A of the patterned conductive layer 230 from a top view perspective.

The patterned conductive layer 240 may be disposed over the ohmic is contact 140. The patterned conductive layer 340 may be disposed over the patterned conductive layer 240. The patterned conductive layer 240′ may be disposed over the ohmic contact 140′. The patterned conductive layer 340′ may be disposed over the patterned conductive layer 240′.

With the design of the ohmic contact 130 having the opening 130A, the ohmic contact 130 can have a relatively small area, and thus the parasitic capacitance Cds1 between the ohmic contact 130 and the parasitic conduction layer 101 can be relatively small accordingly. Hence, despite of the existence of the parasitic capacitance Cds2 between the ohmic contact 140 and the parasitic conduction layer 101, the equivalent capcitace of the capacitances Cds1 and Cds2 in series can be relatively low. Therefore, the device gain, efficiency, and frequency characteristics can be prevented from being adversely affected by the undesirably relatively high parasitic capacitance between the ohmic contact 130 and the parasitic conduction layer 101.

In addition, despite that the ohmic contact 130 has a relatively small area, the drain width (i.e., the length of the ohmic contact 130 along the direction DR1, referring to FIG. 1B which will be illustrated hereinafter) of the semiconductor device 10 can remain about the same as that of the ohmic contact 130 having no opening 130A, and since the current density is determined based on the length of the ohmic contact 130 along the direction DR1, thus the current density may not be undesirably reduced. Therefore, the power efficiency of the semiconductor device 10 can remain satisfactory, which is particularly advantageous to the semiconductor device 10 serving as a power device, the thermal dissipation ability of the semiconductor device 10 can be also satisfactory due to the relatively large drain width, and thus the overall performance of the semiconductor device 10 can be improved.

FIG. 1B is a top view of a portion of a semiconductor device 10 is according to some embodiments of the present disclosure. FIG. 1A may show a cross-sectional view along the cross-sectional line 1A-1A′ in FIG. 1B.

The portion 131 of the ohmic contact 130 may extend substantially in parallel to the portion 132 of the ohmic contact 130 along a direction DR1. The length of the ohmic contact 130 along the direction DR1 may be referred to as the so-called “drain width” of the semiconductor device 10.

The portion 131 of the ohmic contact 130 may have a width w1 along a direction DR2. The direction DR2 may be substantially perpendicular to the direction DR1. The space between the portion 131 and the portion 132 may have a width w2 along the direction DR2. The portion 132 may have a width w3 along the direction DR2. The width 1 may be the same as or different from the width w3. The width w1 may be about 2 μm to about 20 μm. The width w1 may be about 5 μm to about 10 μm. The width w3 may be about 2 μm to about 20 μm. The width w3 may be about 5 μm to about 10 μm. A total width w0 may equal to the sum of the width w1, the width w2 and the width w3. A ratio of the width w1 to the total width w0 may be about 0.1 to about 0.5. A ratio of the width w3 to the total width w0 may be about 0.1 to about 0.5.

Table 1 below provides results of some exemplary semiconductor devices. Each of the exemplary semiconductor devices (E1-E4) can have a structure same or similar to the semiconductor device 10 as described and illustrated with reference to FIGS. 1A-1B. “a” indicates a normalized value of length, “cds1” indicates a normalized value of capacitance, “i” indicates a normalized value of current, “VO” indicates a normalized value of voltage, and “Po” indicates a normalized value of output power. “Freq” refers to the operating frequency and “Pout” refers to the output power. In Table 1, the value of “Efficiency” is determined according to the following formula:

$$Eff = \frac{1}{1 + {ω}^{2} {C}_{ds}^{2} {R}_{p} {R}_{load}} ,$$

where me value of “Cds1” is Table 1 determines the is “Cds” in the above formula. For example, the value of “Efficiency” of E1 is obtained as follows: 1/(1+1*0.2)* η=0.83η, the value of “Efficiency” of E2 is obtained as follows: 1/(1+0.4*0.2)* η=0.93η, and et al.

TABLE 1

| | E1 | E2 | E3 | E4 |
|---|---|---|---|---|
| w1 | 0.5a | 0.2a | 0.1a | 0.05a |
| w0 | a | a | a | a |
| w2 | 0.25a | 0.4a | 0.45a | 0.475a |
| w1/w0 | 0.5 | 0.2 | 0.1 | 0.05 |
| Cds1 | cds1 | 0.4*cds1 | 0.2*cds1 | 0.1*cds1 |
| Freq | 6 GHz | 6 GHz | 6 GHz | 6 GHz |
| Current | i | i | i | 0.5*i |
| Voltage | V0 | V0 | V0 | V0 |
| Efficiency | 0.83η | 0.93η | 0.96η | 0.98η |
| Po | Po | Po | Po | 0.5*Po |

Table 1 shows that when the width w1 of the portion 131 of the ohmic contact 130 is within the exemplary range, the semiconductor device 10 can be provided with relatively low parasitic capacitance, excellent efficiency, and relatively high output power. When the width w1 of the portion 131 of the ohmic contact 130 is relatively low, despite that the parasitic capacitance is low, it may reduce the output power of the semiconductor device 10.

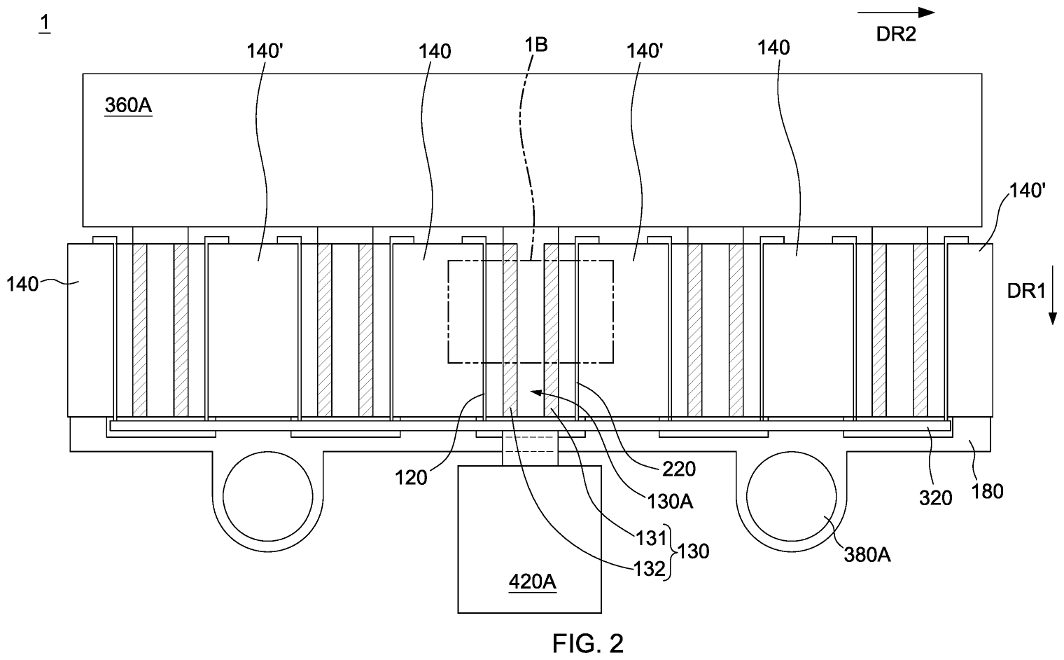

FIG. 2 is a top view of a semiconductor device 1 according to some embodiments of the present disclosure. The structure shown in FIG. 1B can be a partial structure in the dashed line box 1B of FIG. 2. It should be noted that some components are omitted for clarity.

The semiconductor device 1 may include a plurality of ohmic contacts 130. Each of the ohmic contacts 130 may be between one of the is gates 120 and one of the gates 220. Each of the ohmic contacts 130 may have an opening 130A. Each of the openings 130A may be between one of the gates 120 and one of the gates 220. The openings 130A may extend substantially in parallel to the gates 120 and 220. The openings 130A may extend along the direction DR1.

The semiconductor device 1 may further include a gate bus 320 and a gate connection structure 420A. The gate connection structure 420A may be connected to the gate bus 320. The gate bus 320 may connect the gates 120 and 220 to the gate connection structure 420A. The semiconductor device 1 may further include a contact pad 360A (e.g., a drain pad). The ohmic contacts 130 may be connected to the contact pad 360A. The semiconductor device 1 may further include a conductive layer 180 and contact plugs 380A. The contact plugs 380 can serve as source contact plugs. The conductive layer 180 may connect the ohmic contacts 140 and 140′ to the contact plugs 380A.

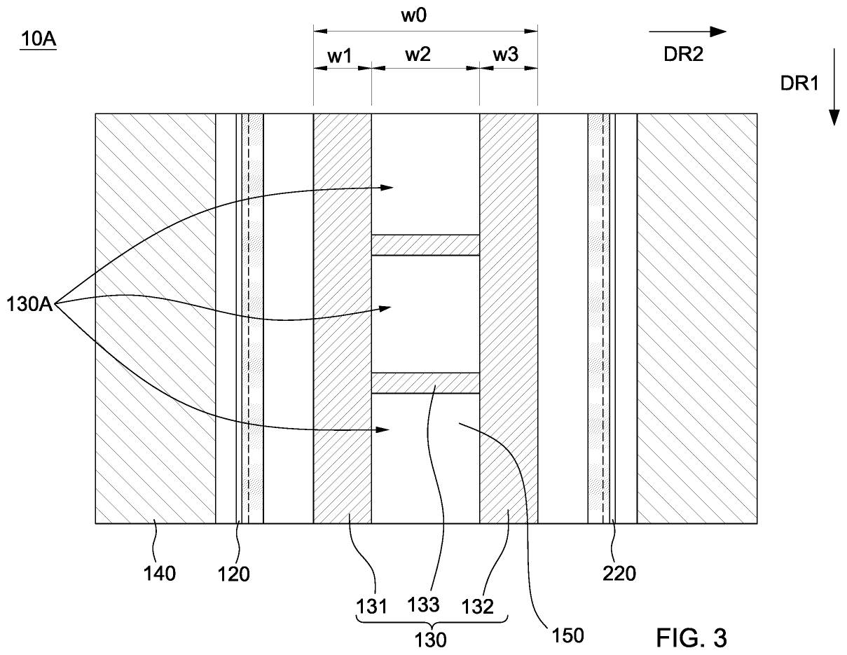

FIG. 3 is a top view of a portion of a semiconductor device 10A according to some embodiments of the present disclosure. The semiconductor device 10A has a structure similar to the semiconductor device 10 shown in FIG. 1B, except that, for example, the ohmic contact 130 has a different structure.

The portion 131 of the ohmic contact 130 may be spaced apart from the portion 132 of the ohmic contact 130, and the ohmic contact 130 may further include a portion 133 (also referred to as “a drain electrode portion”) connecting the portion 131 to the portion 132. The portion 133 may extend substantially perpendicular to the portions 131 and 132. The portion 133 may extend along the direction DR2. The ohmic contact 130 may further include a plurality of portions 133 connecting the portion 131 to the portion 132.

The ohmic contact 130 may include a plurality of the openings 130A. The portion 131, the portion 132, and the portion 133 of the ohmic contact 130 may define the plurality of the openings 130A.

With the design of the portion(s) 133 connecting the portion 131 and the portion 132 of the ohmic contact 130, the balance of the voltages among the portion 131 and the portion 132 can be improved, and thus the voltage distribution among the ohmic contact 130 (e.g., the portions 131, 132 and 133) can be relatively uniform.

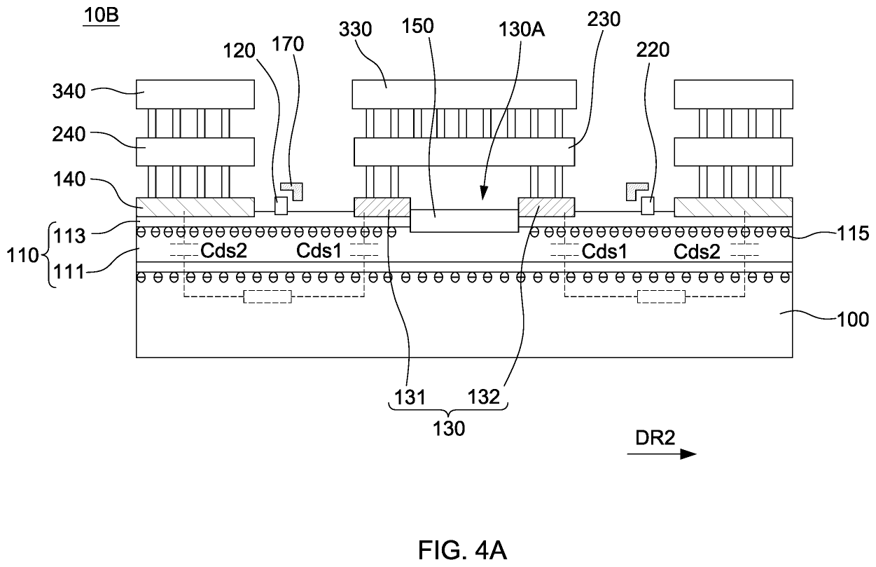

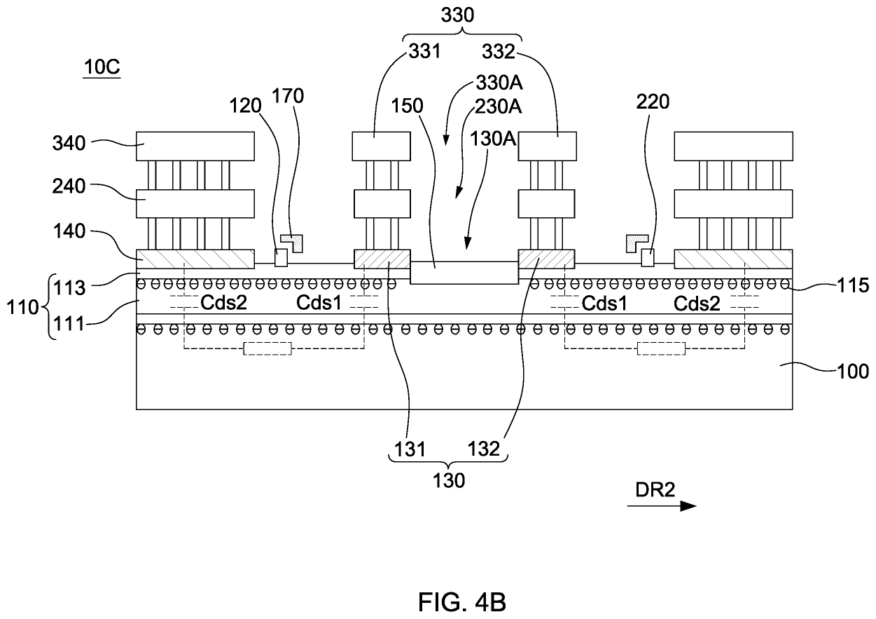

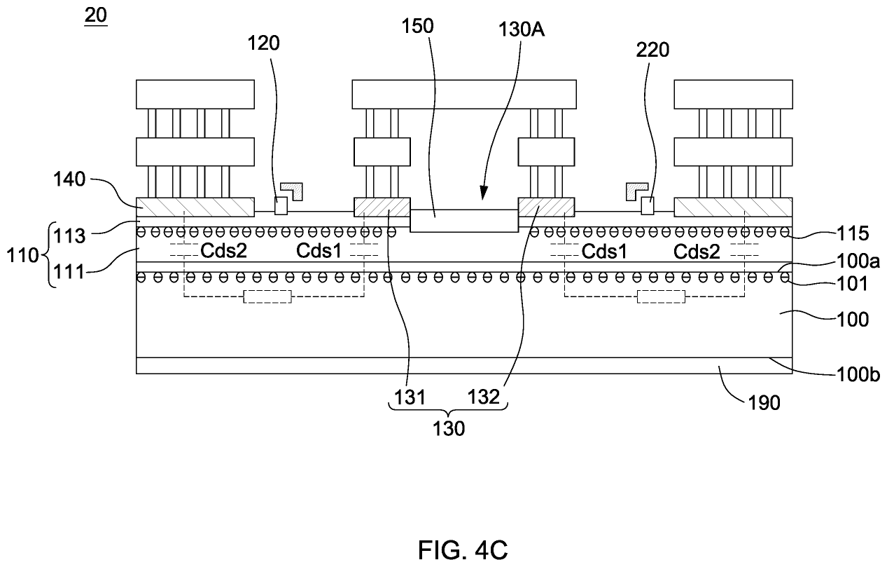

FIG. 4A is a cross-sectional view of a semiconductor device 10B according to some embodiments of the present disclosure. The semiconductor device 10B has a structure similar to the semiconductor device 10 shown in FIG. 1A, except that, for example, the patterned conductive layer 230 has a different structure.

The patterned conductive layer 230 may cover the opening 130A of the ohmic contact 130 from a top view perspective. The patterned conductive layer 230 may cover the structure 150 from a top view perspective. The patterned conductive layer 230 may be free from an opening directly above the opening 130A. The patterned conductive layer 230 may be free from an opening directly above the structure 150. The semiconductor device 10B may not include a cap layer on the nitride semiconductor layer 113.

FIG. 4B is a cross-sectional view of a semiconductor device 10C according to some embodiments of the present disclosure. The semiconductor device 10C has a structure similar to the semiconductor device 10 shown in FIG. 1A, except that, for example, the patterned conductive layer 330 has a different structure.

The patterned conductive layer 330 may have an opening 330A. The patterned conductive layer 330 may include a portion 331 and a portion 332 spaced apart from the portion 331 by the opening 330A. The portions 331 and 332 may extend substantially in parallel to the gate 120. The opening 330A of the patterned conductive layer 330 may be directly above the opening 130A of the ohmic contact 130. The opening 330A of the patterned conductive layer 330 may be directly above the opening 230A of the patterned conductive layer 230. The opening 330A of the patterned conductive layer 330 may be directly above the structure 150.

The opening 330A of the patterned conductive layer 330 may be aligned with the opening 130A of the ohmic contact 130. The opening 330A of the patterned conductive layer 330 may be aligned with the opening 230A of the patterned conductive layer 230.

With the design of the ohmic contact 130 and the patterned conductive layers 230 and 330 all exposing the structure 150, the parasitic capacitance between the parasitic conduction layer 101 and any conductive layer (e.g., the ohmic contact 130, the patterned conductive layer 230, and the patterned conductive layer 330) above the drain region can be further reduced, and thus the electrical performance of the semiconductor device 10C can be effectively prevented from being adversely affected by the undesirably relatively high parasitic capacitance between the parasitic conduction layer 101 and any conductive layer above the drain region.

FIG. 4C is a cross-sectional view of a semiconductor device 20 according to some embodiments of the present disclosure. The semiconductor device 20 has a structure similar to the semiconductor device 10 shown in FIG. 1A, except that, for example, the semiconductor device 20 further includes a conductive layer 190.

The conductive layer 190 may be disposed on the surface 100b (also referred to as “the bottom surface or the back surface”) of the substrate 100. The conductive layer 190 may be or include a metal. The metal may include, for example, but is not limited to, titanium (Ti), tantalum (Ta), tungsten (W), aluminum (Al), cobalt (Co), copper (Cu), nickel (Ni), platinum (Pt), lead (Pb), molybdenum (Mo) and compounds thereof (such as, but not limited to, titanium nitride (TiN), tantalum nitride (TaN), other conductive nitrides, or conductive oxides), metal alloys (such as aluminum-copper alloy (Al—Cu)), or other suitable materials.

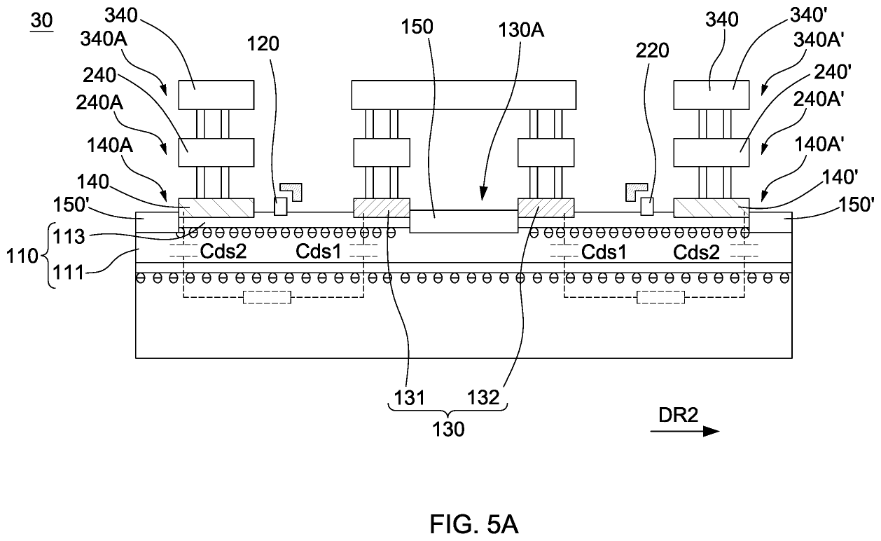

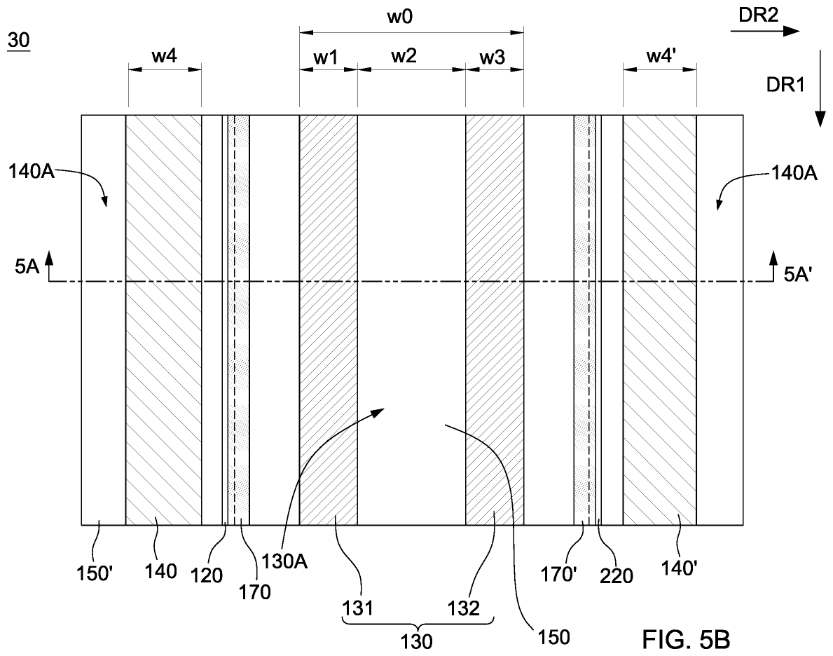

FIG. 5A is a cross-sectional view of a semiconductor device 30 according to some embodiments of the present disclosure. The semiconductor device 30 has a structure similar to the semiconductor device 10 shown in FIG. 1A, except that, for example, the ohmic contact 140 has a different structure.

The ohmic contact 140 may have an opening 140A. The opening 140A of the ohmic contact 140 may expose the nitride semiconductor layer 111. The ohmic contact 140′ may have an opening 140A′. The opening 140A′ of the ohmic contact 140′ may expose the nitride semiconductor layer 111.

The patterned conductive layer 240 may have an opening 240A. The opening 240A of the patterned conductive layer 240 may be directly above the opening 140A of the ohmic contact 140. The opening 240A of the patterned conductive layer 240 may be aligned with the opening 140A of the ohmic contact 140. The patterned conductive layer 240′ may have an opening 240A′. The opening 240A′ of the patterned conductive layer 240 ‘may be directly above the opening 140A’ of the ohmic contact 140′. The opening 240A′ of the patterned conductive layer 240′ may be aligned with is the opening 140A′ of the ohmic contact 140′.

The patterned conductive layer 340 may have an opening 340A. The opening 340A of the patterned conductive layer 340 may be directly above the opening 140A of the ohmic contact 140. The opening 340A of the patterned conductive layer 340 may be aligned with the opening 140A of the ohmic contact 140. The opening 340A of the patterned conductive layer 340 may be aligned with the opening 240A of the patterned conductive layer 240. The patterned conductive layer 340′ may have an opening 340A′. The opening 340A′ of the patterned conductive layer 340′ may be directly above the opening 140A′ of the ohmic contact 140′. The opening 340A′ of the patterned conductive layer 340′ may be aligned with the opening 140A′ of the ohmic contact 140′. The opening 340A′ of the patterned conductive layer 340′ may be aligned with the opening 240A′ of the patterned conductive layer 240′.

The semiconductor device 30 may further include one or more structures 150′ in the semiconductor stack 110. The structure 150′ may be directly below the opening 140A of the ohmic contact 140. The structure 150′ may be directly below the opening 140A′ of the ohmic contact 140′. A material of the structure 150′ may be different from a material of the nitride semiconductor layer 113.

In some other embodiments, the patterned conductive layer 240 may be free from an opening directly above the opening 140A (not shown in FIG. 5A). The patterned conductive layer 240 may cover the opening 140A from a top view perspective. The patterned conductive layer 240′ may be free from an opening directly above the opening 140A′ (not shown in FIG. 5A). The patterned conductive layer 240′ may cover the opening 140A′ from a top view perspective. The patterned conductive layer 340 may be free from an opening directly above the opening 140A (not shown in FIG. 5A). The patterned conductive layer 340 may cover the opening 140A from is a top view perspective. The patterned conductive layer 340′ may be free from an opening directly above the opening 140A′ (not shown in FIG. 5A). The patterned conductive layer 340′ may cover the opening 140A′ from a top view perspective.

With the design of the ohmic contact 130 having the opening 130A and the ohmic contact 140 having the opening 140A, the ohmic contact 130 and the ohmic contact 140 both can have relatively small areas, and thus the parasitic capacitance Cds1 between the ohmic contact 130 and the parasitic conduction layer 101 and the parasitic capacitance Cds2 between the ohmic contact 140 and the parasitic conduction layer 101 can be both relatively small accordingly. Therefore, the device gain, efficiency, and frequency characteristics can be prevented from being adversely affected by the undesirably relatively high parasitic capacitance between the parasitic conduction layer 101 and the ohmic contacts 130 and 140.

FIG. 5B is a top view of a portion of a semiconductor device 30 according to some embodiments of the present disclosure. FIG. 5A may show a cross-sectional view along the cross-sectional line 5A-5A′ in FIG. 5B.

The ohmic contact 140 may extend substantially in parallel to the gate 120 along the direction DR1. The ohmic contact 140′ may extend substantially in parallel to the gate 220 along the direction DR1. The ohmic contact 140 may have a width w4 along the direction DR2. The ohmic contact 140′ may have a width w4′ along the direction DR2. The width 4 may be the same as or different from the width w4′.

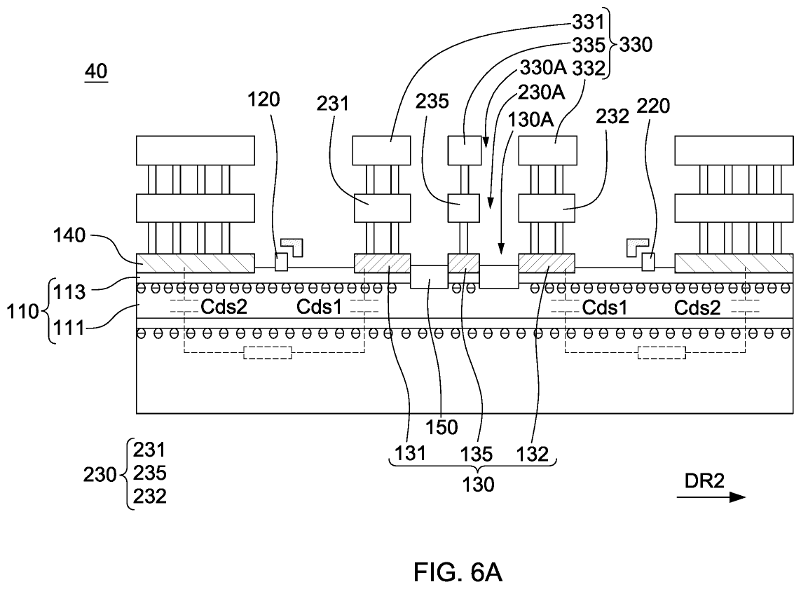

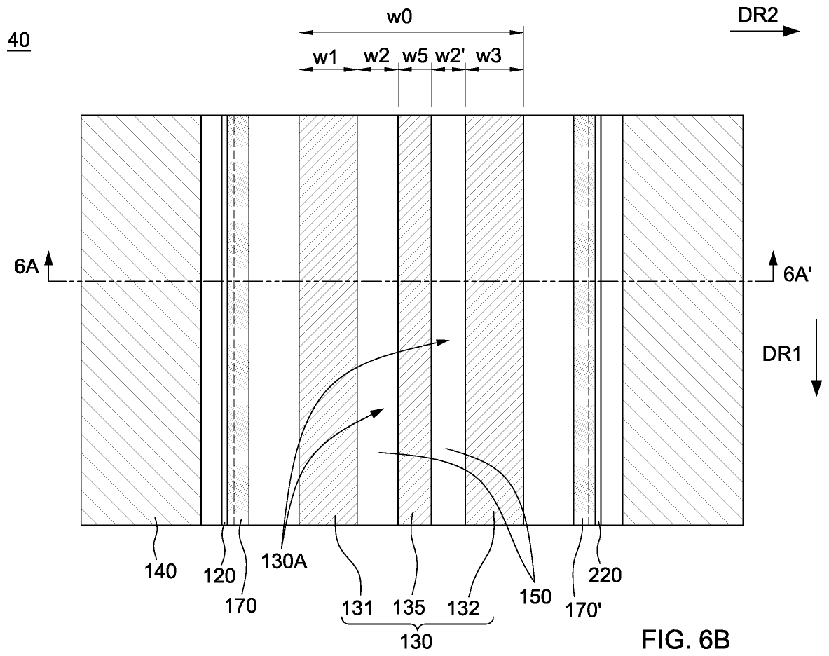

FIG. 6A is a cross-sectional view of a semiconductor device 40 according to some embodiments of the present disclosure. The semiconductor device 40 has a structure similar to the semiconductor device 10 shown in FIG. 1A, except that, for example, the ohmic contact 130 has a different structure.

The ohmic contact 130 may further include a portion 135 (also referred to as “a drain electrode portion”) between the portion 131 and the portion 132. The portion 135 may be spaced apart from the portion 131 of the ohmic contact 130 by one of the openings 130A. The portion 135 may be spaced apart from the portion 132 of the ohmic contact 130 by one of the openings 130A.

The semiconductor device 40 may include a plurality of structures 150 in the semiconductor stack 110. Each of the structures 150 may be exposed by each of the openings 130A. One of the structures 150 may be directly below the space between the portion 131 and the portion 135 of the ohmic contact 130. One of the structures 150 may be directly below the space between the portion 132 and the portion 135 of the ohmic contact 130.

The patterned conductive layer 230 may further include a portion 235 between the portion 231 and the portion 232. The portion 235 of the patterned conductive layer 230 may be electrically connected to the portion 135 of the ohmic contact 130 through one or more conductive vias. The portion 235 may be spaced apart from the portion 231 of the patterned conductive layer 230 by one of the openings 230A. The portion 235 may be spaced apart from the portion 232 of the patterned conductive layer 230 by one of the openings 130A. The portions 231, 232 and 235 of the patterned conductive layer 230 may extend substantially in parallel to the gate 120. Each of the openings 130A of the ohmic contact 130 may be aligned with each of the openings 230A of the patterned conductive layer 230.

The patterned conductive layer 330 may further include a portion 335 between the portion 331 and the portion 332. The portion 335 of the patterned conductive layer 330 may be electrically connected to the portion is 235 of the patterned conductive layer 230 through one or more conductive vias. The portion 335 may be spaced apart from the portion 331 of the patterned conductive layer 330 by one of the openings 330A. The portion 335 may be spaced apart from the portion 332 of the patterned conductive layer 330 by one of the openings 330A. The portions 331, 332 and 335 of the patterned conductive layer 330 may extend substantially in parallel to the gate 120. Each of the openings 130A of the ohmic contact 130 may be aligned with each of the openings 330A of the patterned conductive layer 330. Each of the openings 230A of the patterned conductive layer 230 may be aligned with each of the openings 330A of the patterned conductive layer 330.

FIG. 6B is a top view of a portion of a semiconductor device 40 according to some embodiments of the present disclosure. FIG. 6A may show a cross-sectional view along the cross-sectional line 6A-6A′ in FIG. 6B.

The portion 135 of the ohmic contact 130 may extend along the direction DR1. The portion 135 of the ohmic contact 130 may have a width w5 along the direction DR2. The opening 130A between the portion 131 and the portion 135 may have a width w2 along the direction DR2. The opening 130A between the portion 132 and the portion 135 may have a width w2′ along the direction DR2. The width w2 may be the same as or different from the width w2′. A total width w0 may equal to the sum of the width w1, the width w2, the width w2′, the width w3, and the width w5. A ratio of the width w1 to the total width w0 may be about 0.1 to about 0.5. A ratio of the width w3 to the total width w0 may be about 0.1 to about 0.5.

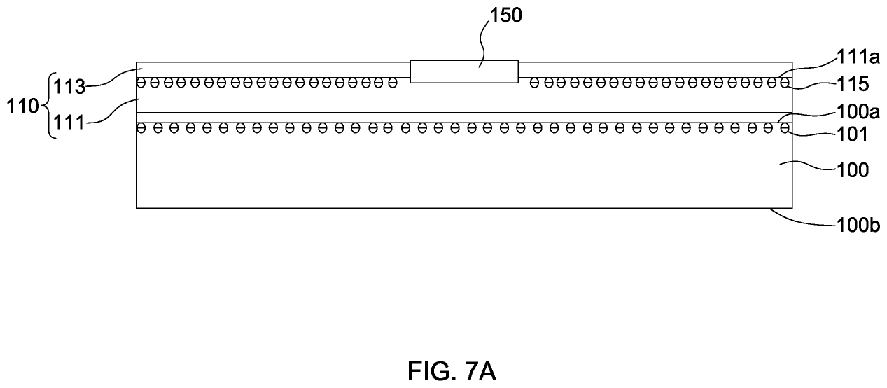

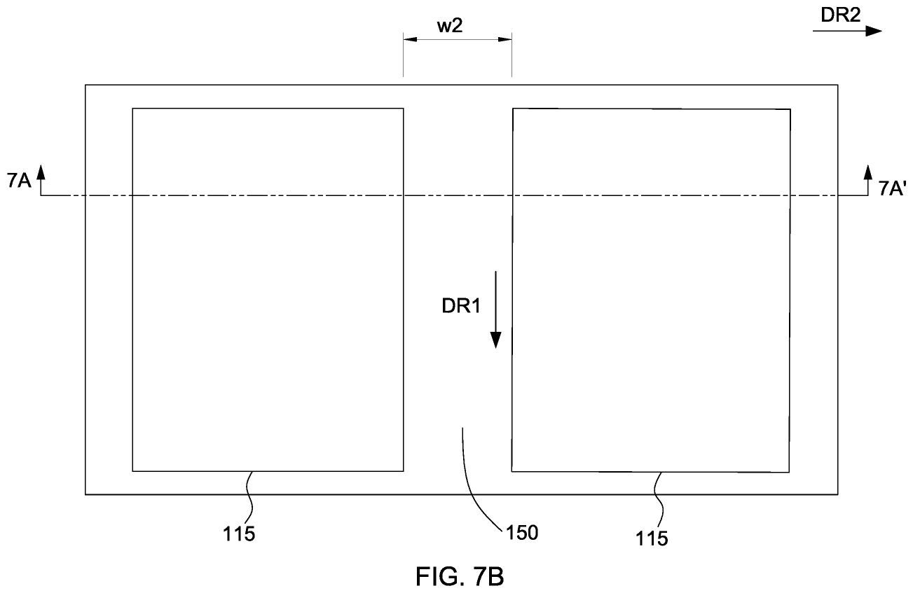

FIGS. 7A, 7B, 8A, 8B, 9A, 9B, 10A and 10B illustrate several operations in manufacturing a semiconductor device 10 according to some embodiments of the present disclosure.

Referring to FIG. 7A, a semiconductor stack 110 may be formed on is a substrate 100. Forming the semiconductor stack 110 may include the following operations: forming a nitride semiconductor layer 111 on the substrate 100, and forming a nitride semiconductor layer 113 on the nitride semiconductor layer 111. The nitride semiconductor layer 113 may have a greater bandgap than that of the nitride semiconductor layer 111 and be in direct contact with a surface 111a of the nitride semiconductor layer 111. The nitride semiconductor layers 111 and 113 may be formed by epitaxial growth. As a heterojunction can be formed between the nitride semiconductor layer 111 and the nitride semiconductor layer 113, e.g., at an interface of the nitride semiconductor layer 111 and the nitride semiconductor layer 113, a 2DEG region 115 may be formed adjacent to the interface of the nitride semiconductor layer 111 and the nitride semiconductor layer 113.

Still referring to FIG. 7A, a structure 150 may be formed in the semiconductor stack 110. A material of the structure 150 may be different from a material of the nitride semiconductor layer 113. The structure 150 may be adjacent to the interface of the nitride semiconductor layer 111 and the nitride semiconductor layer 113 where a 2DEG (e.g., the 2DEG region 115) is supposed to be formed, thus the structure 150 can deplete the 2DEG at the region where the structure 150 is located. Thus, the structure 150 may serve to generate a non-active region where no current passes and have relatively high resistance when the semiconductor device is in operation.

Forming the structure 150 may include performing an implantation process on a portion of the semiconductor stack 110 so as to form the structure 150. Forming the structure 150 may also include the following operations: removing a portion of the nitride semiconductor layer 113 to form a recess in the nitride semiconductor layer 113, and forming a doped group III-V layer, an n-type polysilicon layer, a dielectric material, or a is combination thereof in the recess, so as to form the structure 150.

FIG. 7A may show a cross-sectional view along the cross-sectional line 7A-7A′ in FIG. 7B. Referring to FIG. 7B, the structure 150 may be formed between two active regions (e.g., the 2DEG regions 115). The structure 150 may surround the active regions (e.g., the 2DEG regions 115). Drain electrodes, source electrodes, and gates may be formed on the active regions in subsequent operations. The structure 150 may define one or more non-active regions. The structure 150 between the 2DEG regions 115 may have a width w2 along the direction DR2.

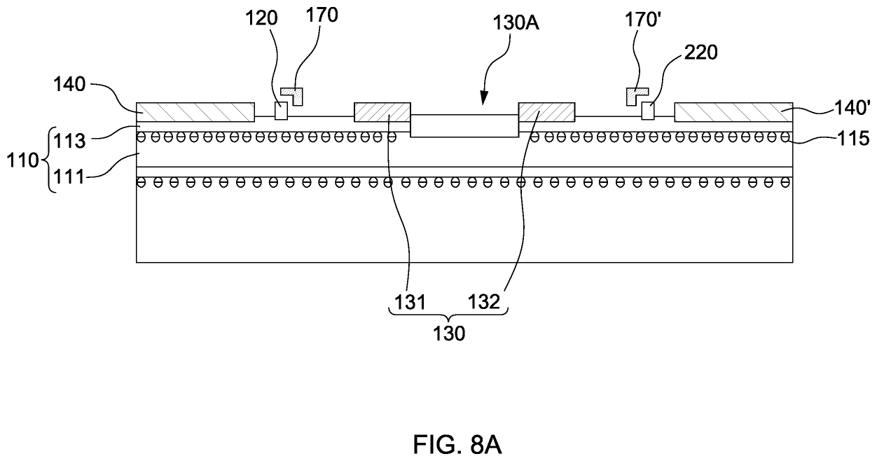

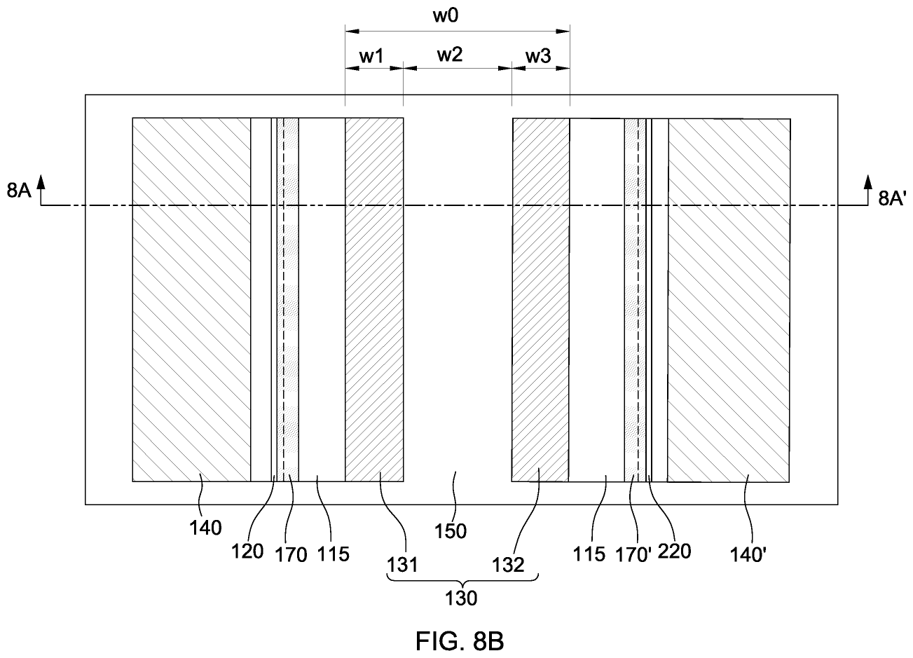

Referring to FIG. 8A, an ohmic contact 130 may be formed over the semiconductor stack 110. The ohmic contact 130 may have an opening 130A exposing the nitride semiconductor layer 111. Forming the ohmic contact 130 may include forming a portion 131 and a portion 132, the portion 131 and the portion 132 define the opening 130A. The ohmic contact 130 may be formed by, for example, depositing an ohmic contact material and then patterning the ohmic contact material by etching to form the portion 131 and the portion 132.

Still referring to FIG. 8A, an ohmic contact 140 may be formed over the semiconductor stack 110. An ohmic contact 140′ may be formed over the semiconductor stack 110. The ohmic contacts 130, 140 and 140′ may be formed in the same operation. The ohmic contacts 130, 140 and 140′ can be formed by physical vapor deposition (PVD), chemical vapor deposition (CVD), atomic layer deposition (ALD), plating, and/or other suitable deposition steps. The structure 150 may be formed in-situ with the formation of the ohmic contacts 130, 140 and 140′. In some other embodiments, the structure 150 may be formed after forming the ohmic contacts 130, 140 and 140′.

Still referring to FIG. 8A, gates 120 and 220 are formed between the ohmic contact 130 and the ohmic contacts 140 and 140′, respectively, from is a top view perspective. Field plates 170 and 170′ may then be formed between the ohmic contact 130 and the ohmic contacts 140 and 140′, respectively, from a top view perspective. The gates 120 and 220 can be formed by physical vapor deposition (PVD), chemical vapor deposition (CVD), atomic layer deposition (ALD), plating, and/or other suitable deposition steps. The field plates 170 and 170′ may be formed by, for example, depositing a conductive material and then patterning the conductive material by etching.

FIG. 8A may show a cross-sectional view along the cross-sectional line 8A-8A′ in FIG. 8B. Referring to FIG. 8B, the ohmic contacts 130, 140 and 140′ may be formed on the active regions (e.g., the 2DEG regions 115). A portion of the nitride semiconductor layer 111 that is free from the 2DEG region 115 may be exposed by a space between the ohmic contact 130 and the ohmic contact 140. A portion of the nitride semiconductor layer 111 that is free from the 2DEG region 115 may be exposed by a space between the ohmic contact 130 and the ohmic contact 140′. The structure 150 may surround the ohmic contacts 130, 140 and 140′ on the active regions (e.g., the 2DEG regions 115).

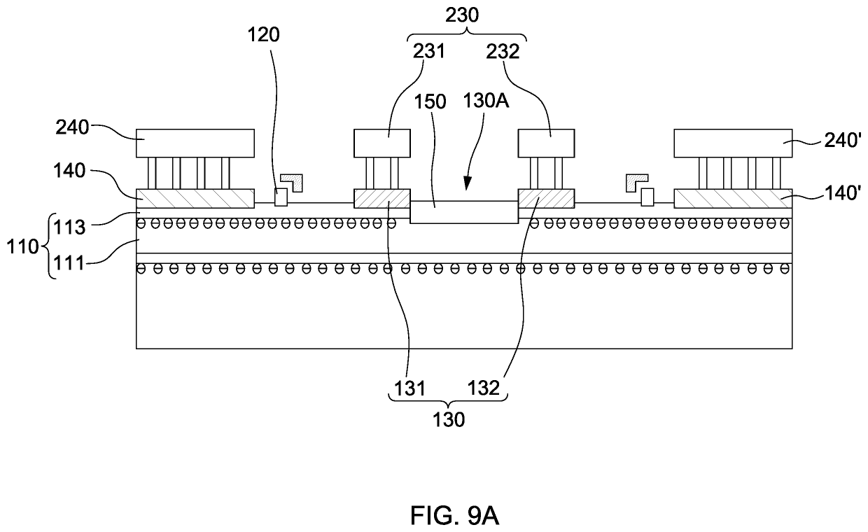

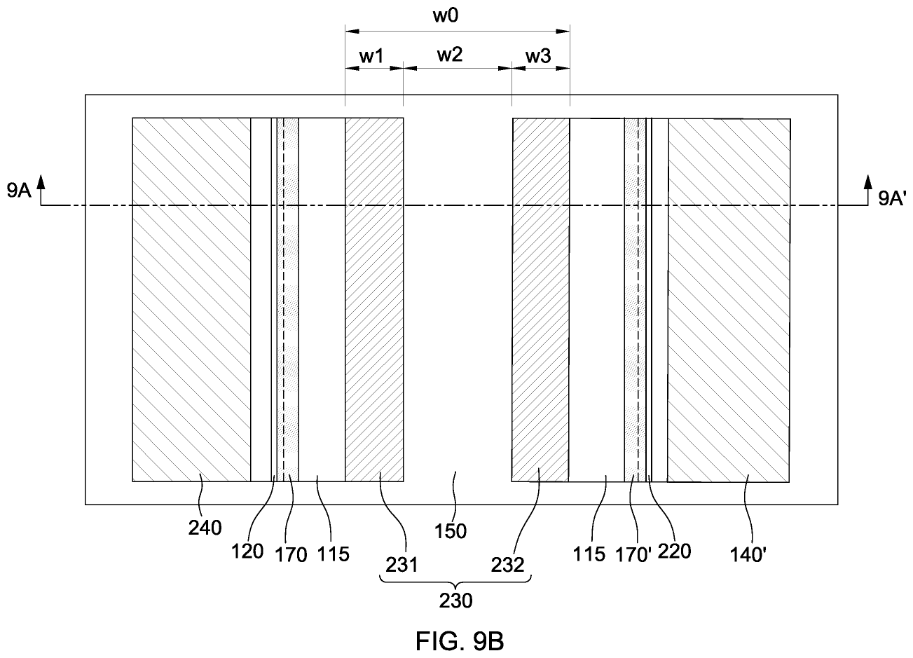

Referring to FIG. 9A, conductive vias are formed over the ohmic contacts 130, 140 and 140′, and patterned conductive layers 230 and 240 are formed over the conductive vias. For example, one or more dielectric layers may be formed between patterned conductive layers 230 and 240 and the conductive vias. The conductive vias may be independently formed by, for example, depositing a dielectric material, removing portions of the dielectric material by etching to form through holes, and then filling a conductive material in the through holes. The patterned conductive layers 230 and 240 may be independently formed by, for example, depositing a conductive material and then patterning the conductive material by etching.

FIG. 9A may show a cross-sectional view along the cross-sectional is line 9A-9A′ in FIG. 9B. Referring to FIG. 9B, the patterned conductive layer 230 may be formed directly above the ohmic contact 130. The patterned conductive layer 240 may be formed directly above the ohmic contact 140. The patterned conductive layer 240′ may be formed directly above the ohmic contact 140′.

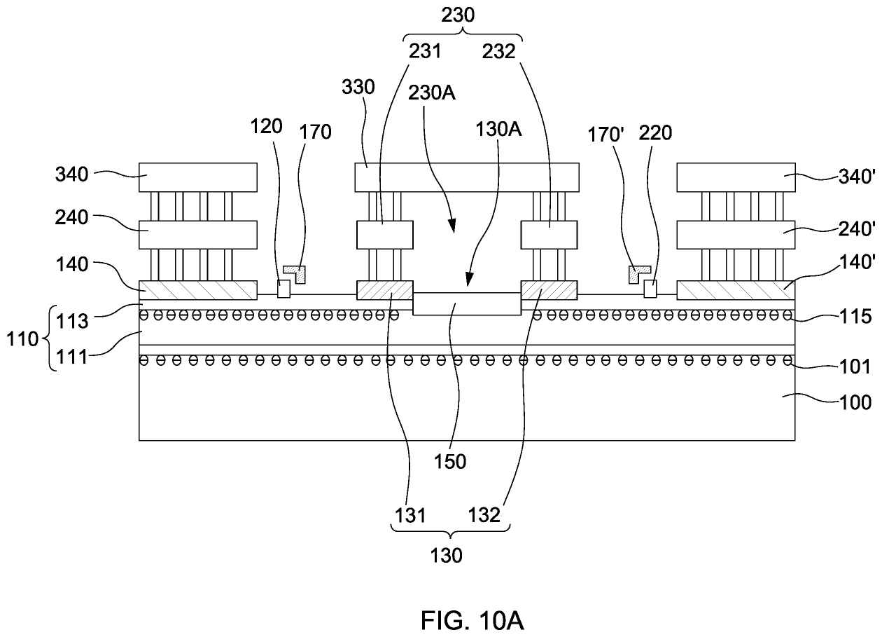

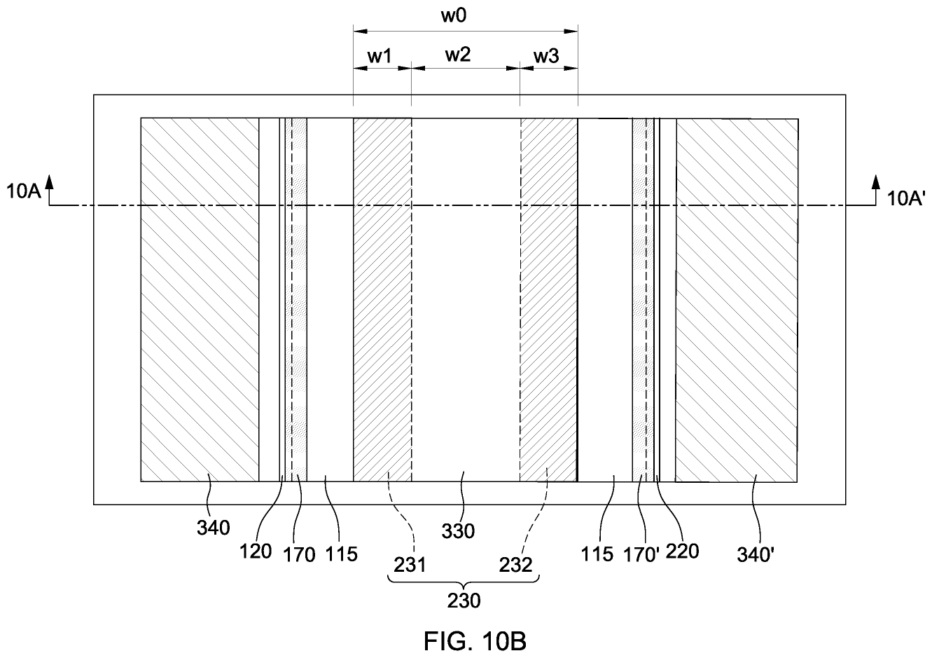

Referring to FIG. 10A, conductive vias are formed over the patterned conductive layers 230 and 240, and patterned conductive layers 330 and 340 are formed over the conductive vias. For example, one or more dielectric layers may be formed between patterned conductive layers 330 and 340 and the conductive vias. The conductive vias may be independently formed by, for example, depositing a dielectric material, removing portions of the dielectric material by etching to form through holes, and then filling a conductive material in the through holes. The patterned conductive layers 330 and 340 may be independently formed by, for example, depositing a conductive material and then patterning the conductive material by etching.

FIG. 10A may show a cross-sectional view along the cross-sectional line 10A-10A′ in FIG. 10B. Referring to FIG. 10B, the patterned conductive layer 330 may be formed directly above the ohmic contact 130 and covering the structure 150 exposed by the patterned conductive layer 230. The patterned conductive layer 340 may be formed directly above the patterned conductive layer 240. The patterned conductive layer 340′ may be formed directly above the patterned conductive layer 240′.

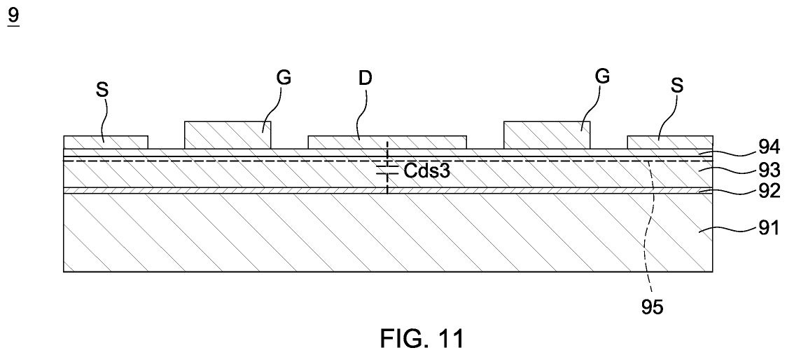

FIG. 11 is a cross-sectional view of a semiconductor device 9 according to some embodiments of the present disclosure. The semiconductor device 9 may include a substrate 91, semiconductor layers 93 and 94, gates G, source electrodes S, and a drain electrode D.

A parasitic conduction layer 92 may be formed in the substrate 91. A 2DEG region 95 may be formed in the nitride semiconductor layer 93. The is drain electrode D has a relatively large area, and thus the parasitic capacitance Cds3 between the drain electrode D and the parasitic conduction layer 92 may be relatively high, which may adversely affect the electrical performance of the semiconductor device 9.

As used herein, spatially relative terms, such as “beneath,” “below,” “lower,” “above,” “upper,” “over,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately,” “substantially,” “substantial” and “about” are used to describe and account for small variations. When used in conduction with an event or circumstance, the terms can refer to instances in which the event of circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

The foregoing outlines features of several embodiments and detailed aspects of the present disclosure. The embodiments described in the present disclosure may be readily used as a basis for designing or modifying other techniques and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

What is claimed is:

1. A semiconductor device, comprising:
a semiconductor stack formed on a substrate, the semiconductor stack having a first nitride semiconductor layer, and a second nitride semiconductor layer formed on the first nitride semiconductor layer and having a wider bandgap than that of the first nitride semiconductor layer; and
a first ohmic contact disposed over the semiconductor stack,
wherein the first ohmic contact has a first opening exposing the first nitride semiconductor layer.

2. The semiconductor device according to claim 1, further comprising:
a structure in the semiconductor stack and exposed by the first opening, wherein a material of the structure is different from a material of is the second nitride semiconductor layer.

3. The semiconductor device according to claim 1, further comprising:
a first patterned conductive layer disposed over the first ohmic contact, the first patterned conductive layer having a second opening directly above the first opening.

4. The semiconductor device according to claim 3, further comprising:
a second patterned conductive layer disposed over the first patterned conductive layer, the second patterned conductive layer having a third opening directly above the first opening.

5. The semiconductor device according to claim 1, wherein the first ohmic contact includes a first portion and a second portion spaced apart by the first opening.

6. The semiconductor device according to claim 1, wherein the first ohmic contact includes a first portion, a second portion spaced apart from the first portion, and a third portion connecting the first portion to the second portion.

7. The semiconductor device according to claim 1, further comprising a second opening.

8. The semiconductor device according to claim 1, further comprising:
a gate disposed over the semiconductor stack; and
a second ohmic contact disposed over the semiconductor stack and on a side of the gate opposite the first ohmic contact, wherein the second ohmic contact has a second opening exposing the first nitride semiconductor layer.

9. A semiconductor device, comprising:
is a semiconductor stack formed on a substrate, the semiconductor stack having a first nitride semiconductor layer, and a second nitride semiconductor layer formed on the first nitride semiconductor layer and having a wider bandgap than that of the first nitride semiconductor layer; and
a first drain electrode portion and a second drain electrode portion disposed over the second nitride semiconductor layer, wherein a space between the first drain electrode portion and the second drain electrode portion exposes the first nitride semiconductor layer.

10. The semiconductor device according to claim 9 further comprising:
a structure in the semiconductor stack and directly below the space between the first drain electrode portion and the second drain electrode portion, wherein a material of the structure is different from a material of the second nitride semiconductor layer.

11. The semiconductor device according to claim 10, further comprising:
a first patterned conductive layer disposed over the first ohmic contact, the first patterned conductive layer having a first opening directly above the structure.

12. The semiconductor device according to claim 11, further comprising:
a second patterned conductive layer disposed over the first patterned conductive layer, the second patterned conductive layer having a second opening directly above the structure.

13. The semiconductor device according to claim 10, wherein the structure includes a doped nitride semiconductor material with a dopant comprising He⁺, N⁺, O⁺, Fe⁺, Ar⁺, Kr⁺, or a combination thereof, a doped is group III-V layer, an n-type polysilicon layer, a dielectric material, or a combination thereof.

14. The semiconductor device according to claim 9, further comprising a third drain electrode portion connecting the first drain electrode portion to the second drain electrode portion.

15. The semiconductor device according to claim 9, wherein the first drain electrode portion extends substantially in parallel to the second drain electrode portion along a first direction.

16. The semiconductor device according to claim 15, wherein the first drain electrode portion has a first width along a second direction perpendicular to the first direction, the space between the first drain electrode portion and the second drain electrode portion has a second width along the second direction, the second drain electrode portion has a third width along the second direction, and a ratio of the first width to a total width of the first width, the second width and the third width is about 0.1 to about 0.5.

17. A method for fabricating a semiconductor device, comprising:
forming a semiconductor stack on a substrate, including:
forming a first nitride semiconductor layer on the substrate; and
forming a second nitride semiconductor layer on the first nitride semiconductor layer; and
forming a first ohmic contact over the semiconductor stack, wherein the first ohmic contact has an opening exposing the first nitride semiconductor layer.

18. The method according to claim 17, wherein forming the first ohmic contact further includes forming a first portion and a second portion, the first portion (and the second portion defining the opening.

19. The method according to claim 17, further comprising:
is forming a structure in the semiconductor stack and directly below the opening, wherein a material of the structure is different from a material of the second nitride semiconductor layer.

20. The method according to claim 19, wherein forming the structure includes performing an implantation process on a portion of the semiconductor stack to form the structure.
